(19) United States
(12) Patent Application Publication
(10) Pub. No.: US 2023/0263042 A1
(43) Pub. Date: Aug. 17, 2023

(54) Quantum dot patterning method using precursor of atomic layer deposition and display device manufactured using the same

(71) Applicant: MYONGJI UNIVERSITY INDUSTRY AND ACADEMIA COOPERATION FOUNDATION, Yongin-si (KR)

(72) Inventors: Seong Yong Cho, Yongin-si (KR); Gi Hwan Kim, Yongin-si (KR); Kyeong Chan Noh, Yongin-si (KR)

(21) Appl. No.: 18/015,224

(22) PCT Filed: Jun. 21, 2021
(86) PCT No.: PCT/KR2021/007772

§ 371 Date: Jan. 9, 2023

(30) Foreign Application Priority Data
Jul. 14, 2020 (KR) 10-2020-0086735

(51) Int. Cl. H10K 71/20; C23C 16/455; H10K 50/115; H10K 71/16; C09K 11/08

(52) U.S. Cl. CPC H10K 71/233; C23C 16/45525; H10K 50/115; H10K 71/166; C09K 11/0838

(57) ABSTRACT

The present disclosure relates to a photolithography process method and a display device manufactured thereby, and more particularly, to a photolithography process method using a quantum dot thin film having greatly improved resistance to an organic solvent by applying a quantum dot coated with ligand onto a substrate and injecting a precursor used in atomic layer deposition, and a display manufactured thereby.

### TECHNICAL FIELD

This application claims priority under 35 U.S.C. § 119 Korean Patent Application No. 10-2020-0086735, filed on Jul. 14, 2020, in the Korean Intellectual Property Office, the disclosure of which is incorporated herein by reference in its entirety.

The present disclosure relates to a quantum dot patterning method and a display device manufactured using the same.

### BACKGROUND ART

Display technology is largely divided into quantum dot light emitting diode technology using quantum dots composed of inorganic materials and organic light emitting diode technology using organic compound films.

A quantum dot (QD) is a nanometer-sized semiconductor particle. At this time, when a size is smaller than an exciton Bohr radius, the movement of electrons is restricted, so an energy level has a discontinuous value, which is called a quantum confinement effect. The quantum dots are used in various optoelectronic devices such as light emitting diodes (LEDs), optical sensors, and solar cells because their electrical and optical properties vary depending on their sizes, shapes, and compositions due to the quantum confinement effect. In particular, the quantum dots are widely used in display devices because they may control a light emitting wavelength depending on their sizes and have excellent color purity and color reproducibility due to their narrow half-width. Recently commercialized TVs under the trade name QLED have significantly improved color reproducibility, which is a disadvantage of LCDs, by replacing fluorescent materials in LEDs on an LCD backplane with quantum dots. This utilizes photo-luminescence (PL) characteristics of quantum dots, and recently, research on electro-luminescence (EL) type devices (QD-LEDs) using quantum dots themselves as a light emitting layer has been actively conducted.

In order to manufacture high-efficiency QD-LEDs, it is very important to synthesize quantum dots with high quantum efficiency. In QD-LEDs, quantum dots are composed of a core and a shell, and the core is a part where light emission actually occurs, and the size of the core determines the light emitting wavelength. The shell serves to improve the stability and quantum efficiency of the quantum dot by preventing the core from being oxidized and reduce the traps on the surface of the core in a form surrounding the core. Therefore, in order to improve the quantum efficiency of the quantum dots, many methods of adjusting the thickness or composition of the shell have been attempted, and in order to facilitate the injection or extraction of the electrons and holes, various methods have been reported, such as introducing rod-structured quantum dots in which different shells are heterojunction centered on a core. Group II-VI quantum dots, represented by Cd and Se, show excellent performance with quantum efficiency approaching 100%. Recently, group III-V quantum dots such as InP have been actively developed to replace Cd, a heavy metal.

However, the existing quantum dot and solution-based light emitting materials are easily dispersed in the solution because they are surrounded by ligands, but it is not easy to coat another layer on the quantum dot thin film due to their low resistance to organic solvents. For this reason, although the quantum dot thin films are patterned through an inkjet printing, transfer printing process, or the like, the yield is low and they are not suitable for the existing semiconductor/display processes. The substitution of the ligand in the liquid phase is also possible, but there are disadvantages in that the quantum dots are deteriorated, the process suitability is low, and an additional process of etching the crosslinked quantum dots is required later.

In order to apply photolithography to the quantum dots, the quantum dots should be coated with a photoresist. Since the solvent of the photoresist dissolves the quantum dots themselves, the process of applying the quantum dots to photolithography is conventionally impossible.

### DISCLOSURE

### Technical Problem

The present disclosure forms a pattern of quantum dots by applying photolithography used in a typical semiconductor process. In particular, an object of the present disclosure is to directly apply the existing semiconductor lithography by directly coating the photoresist on the quantum dots.

Another object of the present disclosure provides a display device manufactured using patterned quantum dots by applying the photolithography.

### Technical Solution

A photolithography process method may include: synthesizing quantum dots surrounded by organic ligands in a solution phase; applying the coated quantum dots onto a substrate; injecting a precursor used in atomic layer deposition (ALD); crosslinking between the coated quantum dots by substituting the organic ligand with the precursor; applying a photoresist onto the crosslinked quantum dots; and positioning a mask spaced apart from above the photoresist and exposing light to partially expose the photoresist.

The crosslinking between the coated quantum dots by substituting the organic ligand with the precursor may further include crosslinking between the coated quantum dots by substituting the organic ligand with the precursor, and then oxidizing the substituted precursor through an atomic layer deposition process.

The quantum dot may be a quantum dot corresponding to a light emitting region.

The quantum dot corresponding to the light emitting region may emit light of one color among red, green, and blue.

The precursor used in the atomic layer deposition may be one selected from the group consisting of diethylzinc (DEZ), trimethylaluminum (TMA), and mixtures thereof.

The crosslinking between the coated quantum dots by substituting the organic ligand with the precursor may be performed in a gas phase.

According to another embodiment of the present disclosure, a display device may be manufactured by one of the process methods.

### Advantageous Effects

According to the present disclosure, an atomic layer deposition precursor is introduced to substitute surface ligands of quantum dots, and ultimately form crosslinking on a surface of quantum dots to have resistance to solvents. Therefore, due to the securing of the resistance to the solvent of the quantum dots, it is possible to apply photolithography in the conventional semiconductor/display field by coating the existing photoresist on the quantum dots, thereby enabling quantum dot patterning through photolithography used in typical semiconductor processes.

In addition, it is possible to shorten a process time for patterning quantum dots in the display device manufacturing process and simplify the overall process.

### DESCRIPTION OF DRAWINGS

The accompanying drawings, which are included to provide a further understanding of the present disclosure and are incorporated in and constitute a part of this specification, illustrate embodiments of the present disclosure and, together with the description, serve to explain the principles of the present disclosure.

FIG. 1 is a graph showing the intensity of light according to a wavelength before (as-prepared) and after (after toluene) a quantum dot thin film to which an atomic layer deposition (ALD) process is not applied is treated with toluene according to Comparative Example of the present disclosure;

FIG. 2 is a graph showing a quantum dot thin film (DEZ pulse) after injecting a precursor (DEZ) of atomic layer deposition (ALD) for 0.5 seconds according to an embodiment of the present disclosure and the intensity of light according to a wavelength after (after toluene) treating the quantum dot thin film with toluene according to an embodiment of the present disclosure;

FIG. 3 is a graph showing a quantum dot thin film (ZnOALD20 cycles) after injecting a precursor (DEZ) of atomic layer deposition (ALD) for 0.5 seconds and performing 20 cycles of the atomic layer deposition according to an embodiment of the present disclosure and the intensity of light according to a wavelength after (after toluene) treating the quantum dot thin film with toluene according to an embodiment of the present disclosure;

FIG. 4 is an optical micrograph showing resistance to a solvent of a quantum dot thin film to which the ALD process is not applied according to Comparative Example of the present disclosure;

FIG. 5 is an optical micrograph illustrating resistance to a solvent of a quantum dot thin film (DEZ pulse) after injecting a precursor (DEZ) of atomic layer deposition (ALD) for 0.5 seconds according to an embodiment of the present disclosure;

FIG. 6 is an optical micrograph illustrating resistance to a solvent of a quantum dot thin film (ZnOALD20 cycles) after injecting a precursor (DEZ) of atomic layer deposition (ALD) for 0.5 seconds and performing 20 cycles of the atomic layer deposition according to an embodiment of the present disclosure;

FIG. 7 is a photograph showing that a pattern having a micrometer-level resolution of a quantum dot thin film is formed after injecting the precursor (DEZ) through the atomic layer deposition; and

FIG. 8 is a graph comparing photoluminescence (PL) according to a wavelength after the quantum dot patterning based on the atomic layer deposition.

### MODE FOR DISCLOSURE

Hereinafter, the present disclosure will be described below in detail with reference to the accompanying drawings.

Terms and words used in the present specification and claims are not to be construed as general or dictionary meanings, but are to be construed as meanings and concepts meeting the technical ideas of the present disclosure based on a principle that the present inventors may appropriately define the concepts of terms in order to describe their inventions in the best mode.

Therefore, configurations described in exemplary embodiments and the accompanying drawings of the present disclosure do not represent all of the technical spirits of the present disclosure, but are merely the most preferable embodiments. Therefore, the present disclosure should be construed as including all the changes, equivalents, and substitutions included in the spirit and scope of the present disclosure at the time of filing this application.

A photolithography process according to an embodiment of the present disclosure may include the following steps.

First, quantum dots surrounded by organic ligands are synthesized in a solution phase. The quantum dots may be used without limitation as long as they emit light. For example, it may be one or more of group II-VI quantum dots, group III-V quantum dots, and perovskite quantum dots, and the perovskite quantum dots may be preferably used, but are not limited thereto.

The wavelength of light emitted by the quantum dots varies depending on their size, and for use in the display devices, the quantum dots that emit red (R), green (G), and blue (B), respectively, are preferably required. The larger the size of the quantum dot, the longer the wavelength of the emitted light. Preferably, in order to emit visible light, a diameter of the quantum dot core is between 1 nm and 3 nm, which may be suitable for use in a display device.

The organic ligand serves to help disperse quantum dots well in a solvent, and generally used organic ligands may be used. Specifically, primary amines such as 1-dodecanethiol, 3-mercaptopropionic acid, trioctylphosphine, trioctylphosphine oxide, oleic acid, oleic acid, and oleylamine may be exemplified. Preferably, the organic ligand may be wet-coated on the surface of the shell of the quantum dot core emitting light of one color of red, green, and blue.

Next, the quantum dots surrounded by the organic ligands may be applied onto a substrate, and the precursor used in the atomic layer deposition may be injected. The substrate may operate as a light emitting device through the photolithography process of the present disclosure.

The precursor is not particularly limited as long as it may cross-link the surface of the quantum dots in the gas phase as an oxide-based precursor, but preferably one or more of diethylzinc (DEZ) and trimethylaluminum (TMA) may be used.

The injection of the precursor may preferably be performed for 0.3 to 0.7 seconds, and the precursor may undergo a substitution reaction with the organic ligand of the quantum dots to provide crosslinkability between the quantum dots even with a short precursor injection time. The precursor may be injected in the gas phase and undergo substitution reaction with the organic ligand in the gas phase, and an oxidizing agent such as H₂O or O₃ may be additionally added and the atomic layer deposition may be used. In the atomic layer deposition, an oxidation reaction may occur sufficiently with only one cycle.

In an embodiment of the present disclosure, diethyl zinc is injected for 0.5 seconds to cause a substitution reaction with organic ligands of quantum dots, and then H₂O is added and diethyl zinc (DEZ) was oxidized to zinc oxide (ZnO) through a general atomic layer deposition.

As the organic ligand coated on the surface of the quantum dots is substituted with the precursor which is an inorganic matter, the crosslinking between the quantum dots occurs. When the crosslinking between the quantum dots occurs, the solubility of the quantum dot thin film in the organic solvent of the photoresist used in a general photolithography process is greatly reduced, and the resistance to the solvent is improved. In addition, when the organic ligand-substituted precursor is oxidized through the atomic layer deposition, the crosslinking between the quantum dots becomes stronger and the resistance of the organic solvent to the organic solvent of the quantum dot thin film is further increased. The oxidation process may be performed using an oxidizing agent such as O₂ or H₂O included in the atmosphere while the precursor is exposed to the atmosphere in the general atomic layer deposition process, but the precursor may be oxidized by adding an additional oxidizing agent. As the resistance to the organic solvent of the quantum dot thin film increases due to the oxidation of the precursor, the patterning may be elaborated in the photolithography process, and as a result, a high-resolution display may be implemented.

After applying the photoresist (PR) onto the crosslinked quantum dots, a general photolithography process is performed. When the atomic layer deposition of the present disclosure is used, the quantum dot damage may not occur even when the photoresist is directly applied onto the crosslinked quantum dots. Conventionally, the organic ligands of quantum dots are dissolved in the organic solvent of the photoresist used in the photolithography process, so the quantum dots may not be applied to a photolithography process. However, the present disclosure makes it possible to apply the photolithography process to the quantum dot patterning through the atomic layer deposition, and furthermore, there is an advantage of simplifying the quantum dot patterning process and shortening the process time through the atomic layer deposition using a low vacuum.

The photoresist PR may be partially exposed by positioning a mask spaced apart from above the applied photoresist and being exposed to light. The light source may be ultraviolet light. A pattern may be formed on the photoresist PR layer by dissolving the photoresist using a developer generally used in photolithography using a structural difference between a portion exposed by a light source and a portion not exposed. Examples of the developing solution include inorganic alkalis such as sodium hydroxide, sodium carbonate, sodium silicate, ammonia water, organic amines such as ethylamine, diethylamine, triethylamine, and triethanolamine, aqueous solutions such as quaternary ammonium salts such as tetramethylammonium hydroxide and tetrabutylammonium hydroxide, and a water-soluble organic solvent such as methanol or ethanol or an aqueous solution containing an appropriate amount of surfactant, if necessary.

During the developing process, since the photoresist is dissolved by the developing solution and the portion where the quantum dot thin film is exposed is also dissolved in the developing solution, an etching process required in general photolithography may be omitted. Therefore, the process efficiency may be expected to be improved due to the simplification of the process.

By repeating the photolithography process with different colors emitted by the quantum dots, a multi-color display device may be manufactured. The display device may be specifically a smart phone, a television, a mobile phone, an electronic watch, an electronic display board, or a computer monitor, but is not limited thereto.

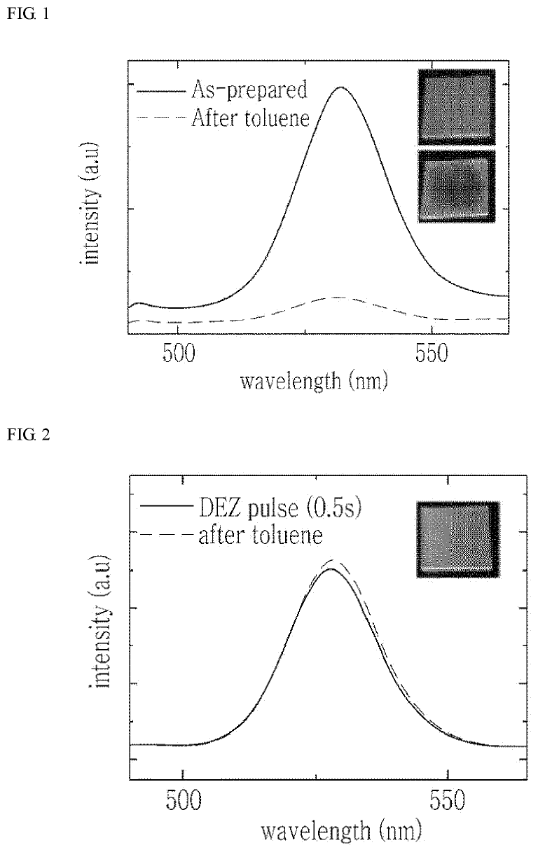

FIGS. 1 and 4 are Comparative Examples of the present disclosure, and illustrate the amount of light and the solvent resistance when the quantum dots coated with organic ligands are applied onto the substrate, respectively. FIG. 1 is a graph comparing the amount of light before and after treatment with toluene, an organic solvent. Although the quantum dots were applied onto the substrate, since the cross-linking between the quantum dots was not performed, all the quantum dots were dissolved during the organic solvent treatment, so almost no quantum dots remain on the substrate anymore. As a result, it can be seen that the amount of light emitted from the quantum dots on the substrate was insignificant. It can be seen from FIG. 4 that after the quantum dots coated with the organic ligands are treated with toluene, the quantum dot pattern almost disappears, and thus, it is difficult to use the quantum dots in a display.

FIGS. 2 and 5 illustrate, as an embodiment of the present disclosure, the amount of light and the solvent resistance for the quantum dot thin film (DEZ) in which the precursor (DEZ) of the atomic layer deposition (ALD) is injected for 0.5 seconds to substitute the organic ligands on the surface of the quantum dots with the precursor to form the crosslinking FIG. 2 is a graph comparing the amount of light before and after treatment with toluene, an organic solvent, and it may be seen that the quantum dot thin film is hardly dissolved in toluene through the substitution reaction of the precursor, so there is little change in the amount of light. FIG. 5 also illustrates that a large portion of the quantum dot pattern is maintained even after toluene treatment, wherein it can be seen that the solvent resistance of the quantum dot thin film is greatly improved only by injecting the precursor.

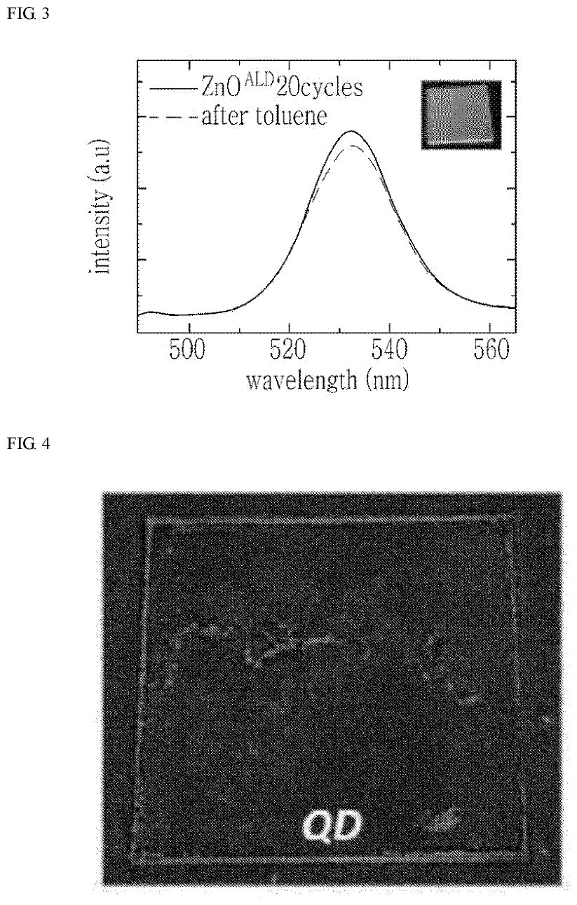

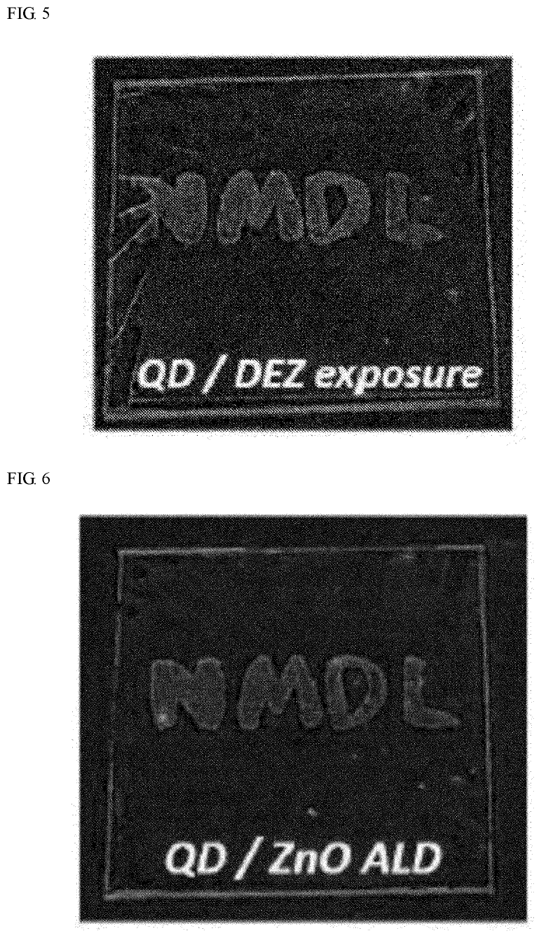

FIGS. 3 and 6 illustrate, as an embodiment of the present disclosure, experimental data obtained when the diethyl zinc (DEZ), the precursor substituted with the organic ligand, is oxidized to zinc oxide (ZnO) by additionally repeating the atomic layer deposition on the quantum dot thin film of FIGS. 2 and 5 for 20 cycles. Referring to FIG. 3, it can be seen that a high amount of light is maintained without a significant difference compared to FIG. 2 before oxidizing the precursor. However, referring to FIG. 6, it can be seen that the resistance to the solvent is improved compared to FIG. 5 before oxidizing the precursor, and thus, more sophisticated patterning is possible. Therefore, it can be seen that a higher resolution display device may be manufactured by additionally oxidizing the precursor. In addition, since the oxidized ZnO serves as a charge transport layer of the quantum dot light emitting diode, it does not need to be removed separately, and rather, the charge transport layer and the light emitting layer have the effect of forming a pattern together.

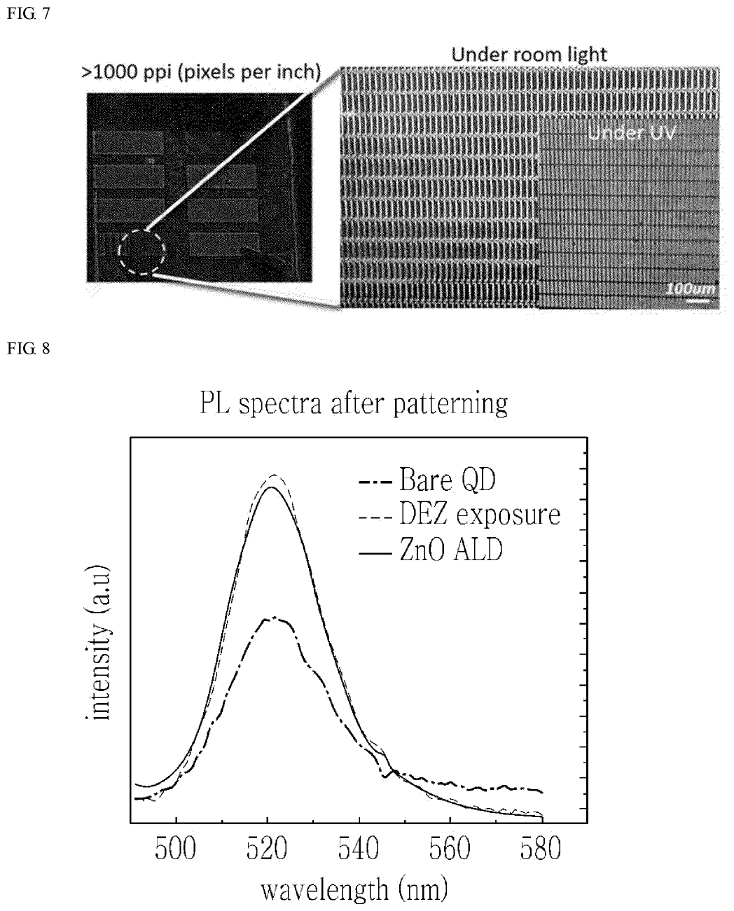

FIG. 7 is a photograph showing that a micrometer-level pattern of the quantum dot thin film is formed after injecting the precursor (DEZ) through the atomic layer deposition according to another embodiment of the present disclosure, and illustrates that a resolution of 1600 pixels per inch (ppi), which is a level applicable to current displays, is implemented.

FIG. 8 illustrates experimental data comparing the amount of light according to the wavelength when the quantum dot patterning is performed by applying the typical photolithography to the quantum dot thin film (DEZ exposure, Example 1) after injecting the precursor (DEZ) of the atomic layer deposition (ALD), which is an embodiment of the present disclosure, for 0.5 seconds compared to the quantum dot thin film (Bare QD, Comparative Example) to which the ALD process is not applied and the quantum dot thin film (ZnO ALD, Example 2) after injecting the precursor (DEZ) of atomic layer deposition (ALD) for 0.5 seconds and then performing 20 cycles of atomic layer deposition. It shows that Examples 1 and 2 exhibit high photoluminescence (PL) in the visible ray region compared to Comparative Example.

While exemplary embodiments have been shown and described above, it will be apparent to those skilled in the art that modifications and variations could be made without departing from the scope of the present disclosure as defined by the appended claims.

1. A photolithography process method, comprising:
a) synthesizing quantum dots surrounded by organic ligands in a solution phase;
b) applying the coated quantum dots onto a substrate;
c) injecting a precursor used in atomic layer deposition (ALD);
d) crosslinking between the coated quantum dots by substituting the organic ligand with the precursor;
e) applying a photoresist onto the crosslinked quantum dots; and
f) positioning a mask spaced apart from above the photoresist and exposing light to partially expose the photoresist.

2. The method of claim 1, wherein step d) further includes crosslinking between the coated quantum dots by substituting the organic ligand with the precursor, and then oxidizing the substituted precursor through an atomic layer deposition process.

3. The method of claim 1, wherein the quantum dots are quantum dots corresponding to a light emitting region.

4. The method of claim 3, wherein the quantum dots corresponding to the light emitting region emit light of one color among red, green, and blue.

5. The method of claim 1, wherein the precursor in step c) is one selected from the group consisting of diethylzinc (DEZ), trimethylaluminum (TMA), and mixtures thereof.

6. The method of claim 2, wherein the precursor in step c) is diethylzinc (DEZ), and through the oxidation process in step d), the diethyl zinc is oxidized to zinc oxide (ZnO).

7. The method of claim 2, wherein the precursor in step c) is trimethylaluminum (TMA), and through the oxidation process in step d), the trimethyl aluminum is oxidized to aluminum oxide (Al₂O₃).

8. The method of claim 1, wherein the crosslinking in step d) is performed in a gas phase.

9. A display device manufactured by a photolithography process method, comprising:
a) synthesizing quantum dots surrounded by organic ligands in a solution phase;
b) applying the coated quantum dots onto a substrate;
c) injecting a precursor used in atomic layer deposition (ALD);
d) crosslinking between the coated quantum dots by substituting the organic ligand with the precursor;
e) applying a photoresist onto the crosslinked quantum dots; and
f) positioning a mask spaced apart from above the photoresist and exposing light to partially expose the photoresist.
